(19) United States
(12) Patent Application Publication
(10) Pub. No.: US 2007/0001291 A1
(43) Pub. Date: Jan. 4, 2007

(54) Anti-warp heat spreader for semiconductor devices

(75) Inventors: Soo Gil Park, Dresden (DE); Kenneth Rebibis, Dresden (DE); Juergen Grafe, Dresden (DE)

Correspondence Address: SLATER & MATSIL LLP, 17950 PRESTON ROAD, SUITE 1000, DALLAS, TX, 75252, US

(73) Assignee: Infineon Technologies AG

(21) Appl. No.: 11/267,536

(22) Filed: Nov. 4, 2005

Related U.S. Application Data
(60) Provisional application No. 60/695,640, filed on Jun. 30, 2005.

(51) Int. Cl. H01L 23/34

(52) U.S. Cl. 257/718

(57) ABSTRACT

An anti-warp heat spreader for semiconductor devices is disclosed, wherein the heat spreader is made of a metal sheet of substantially constant thickness, the metal sheet being perforated by at least one opening to allow for the percolation of an adhesive or a resin. The heat spreader is designed to strengthen the package by providing a strong bond between its components, i.e., the circuit board, die, heat spreader and reinforcing frame. At the same time the heat generated by the die during operation is efficiently dissipated. The heat spreader can easily be attached to the die by positioning it in the mold used to produce the reinforcing frame and then fill the mold with a mold compound. The mold compound will easily flow through the opening or openings, thereby filling the gap between the heat spreader and the die. The mold compound replaces the air that escapes from the gap through the opening or openings. Thus, a strong and intense connection between the die and the heat spreader is constituted. The bonding layer underneath the heat spreader and the reinforcing frame above the heat spreader are firmly. interconnected through the opening or openings.

This application claims the benefit of U.S. Provisional Application No. 60/695,640, filed on Jun. 30, 2005, entitled Anti-Warp Heat Spreader for Semiconductor Devices, which application is hereby incorporated herein by reference.

### TECHNICAL FIELD

This invention relates to an anti-warp heat spreader for semiconductor devices such as integrated circuits (“ICs”), semiconductor chips and the like and a semiconductor device containing such heat spreader.

### BACKGROUND

Anti-warp heat spreaders have been described in prior art patents. For example U.S. Pat. No. 6,848,172 B2 (Fitzgerald et al.), U.S. Pat. No. 5,998,241 (Niwa), Japanese Patent No. 07302866 A (Okikawa, et al.), Japanese Patent No. 10056110 A (Muramatsu, et al.), and Japanese Patent No. 09008186 A (Imura, et al.) all describe related devices. Each of these prior art references is incorporated herein by reference.

A semiconductor device usually consists of a semiconductor chip (the so-called die) and a circuit board. The die is mounted on the top surface of the circuit board by means of a synthetic resin and is electrically connected to the bottom surface of the circuit board by means of bonding wires that extend from the bottom side of the die to the bottom surface of the circuit board through an opening in the circuit board, where the bonding wires are connected to conductor tracks that are located on that bottom surface.

At least the top surface of the circuit board, including the die, (the so-called package) is usually covered by a synthetic resin to form a reinforcing frame atop the package that protects the die from potentially damaging impacts. Especially for high performance semiconductor chips, a heat spreader, sometimes combined with a heat sink, is frequently added to the package in order to spread the heat generated by the die when in operation, thus improving its dissipation. Usually the heat spreader is bonded on top of the die by means of a synthetic resin. In the majority of cases where a heat sink is to be used, the heat spreader remains exposed, i.e., it is not covered by the reinforcing frame.

Efforts have been made to utilize such heat spreaders as a reinforcing member in order to strengthen the package and prevent heat induced warpage that can lead to package failure. However, experience shows that the solutions that have been proposed so far are not very effective so that there is a need for a heat spreader that improves the mechanical strength of semiconductor devices in order to minimize warpage of the device caused by heat.

### SUMMARY OF THE INVENTION

In one aspect, the present invention provides a heat spreader for semiconductor devices that effectively spreads heat and aids in the dissipation of heat and, at the same time, reinforces the device to minimize heat-induced warpage. In a further aspect, the invention provides a semiconductor device with such heat spreader, which is well protected against thermal failure due to overheating as well as against mechanical failure because of thermal deformation at the same time.

For example, an anti-warp heat spreader can be provided for semiconductor devices, wherein the heat spreader is made of a metal sheet of substantially constant thickness. The metal sheet is perforated by at least one opening to allow for the passage of a mold compound.

The heat spreader is designed to strengthen the package by providing a strong bond between its components, i.e. the circuit board, die, heat spreader and reinforcing frame. At the same time the heat generated by the die during operation is efficiently dissipated. The heat spreader can easily be attached to the die by positioning it in the mold used to produce the reinforcing frame and then fill the mold with a mold compound. The mold compound will easily flow through the opening or openings, thereby filling the gap between the heat spreader and the die. The mold compound replaces the air that escapes from the gap through the opening or openings. Thus, a strong and intense connection between the die and the heat spreader is constituted. The bonding layer underneath the heat spreader and the reinforcing frame above the heat spreader are firmly interconnected through the opening or openings.

According to another aspect of the invention, the metal sheet is substantially flat and has at least one groove wherein at least one opening is placed. The groove is made so as to locally reduce the thickness of the metal sheet. It can, for example, be made by etching the top surface of the metal sheet. The mold compound fills the groove during molding and establishes a reinforcing frame after curing. It is especially advantageous to provide furrows alongside each groove to collect excess mold compound which, after filling the groove, bleeds out during molding. That way, the top surface of the heat spreader remains free of mold compound.

According to another aspect of the invention, the metal sheet has a primary group of grooves running parallel to each other and a secondary group of grooves running parallel to each other and intersecting the primary group of grooves. Thus, a grid of grooves surrounding the die can be formed. This makes it easier to separate a package from a group of packages that have been molded at the same time by simply cutting or sawing them apart. It is beneficial to arrange a multitude of openings in columns and rows along the grooves. Thus, the reinforcing frame is connected to the circuit board along the edges of each package.

In another embodiment of the present invention the heat spreader further has a stiffening corrugation. It is known that a corrugated plate is stiffer than a flat plate of the same thickness. Therefore, a corrugated metal sheet, when used as a heat spreader, gives the package a greater strength. The stiffening corrugation can, for example, have the shape of one or more ripples or cups. Within the scope of the invention is any combination of ripples and cups formed in the metal plate. Regardless of the actual shape used for the corrugation, it is advantageous to arrange the opening or openings in the groove formed by a ripple or in the bottom of a cup, respectively.

As with the flat metal sheet used in the embodiment described above, the stiffening corrugation can advantageously comprise a primary group of ripples running parallel to each other. This primary group of ripples may be complemented by a secondary group of ripples also running parallel to each other and intersecting the primary group of ripples, thereby being disrupted at intersections. The arrangement of two groups of parallel ripples running in two different directions gives the package extraordinary stiffness regardless of the effective direction of an exterior impact and for every thermal load case.

For an even higher stiffness, it may be useful to have the primary group of ripples project to one side of the metal sheet and the secondary group of ripples project to the other side of the metal sheet.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1A is a cross-section view of a component assembly including several dies on a common circuit board in which a first embodiment of a heat spreader with grooves is used;

FIG. 1B is a top view of the heat spreader with grooves;

FIG. 1C is a partial cross-section view of the heat spreader with grooves;

FIG. 2A is a cross-section view of a component assembly including several dies on a common circuit board in which a first model of a second embodiment of a heat spreader with ripples is used;

FIG. 2B is a cross-section view of a component assembly including several dies on a common circuit board in which a second model of a second embodiment of a heat spreader with ripples is used;

FIG. 2C is a cross-section view of a component assembly including several dies on a common circuit board in which a third model of a second embodiment of a heat spreader with ripples is used;

FIG. 3A is a top view of the first and third models of the heat spreader with ripples;

FIG. 3B is a top view of the second model of the heat spreader with ripples;

FIG. 4A is a top view of the first and third models of the heat spreader with ripples attached to a substrate with big or small dies;

FIG. 4B is a top view of the second model of the heat spreader with ripples attached to a substrate with big or small dies;

FIG. 5, consisting of FIGS. 5a-5d, illustrates the manufacturing process for a package using the first model of the second embodiment of the heat spreader;

FIG. 6, consisting of FIGS. 6a-6d, illustrates the manufacturing process for a package using the second model of the second embodiment of the heat spreader;

FIG. 7, consisting of FIGS. 7a-7d, illustrates the manufacturing process for a package using the third model of the second embodiment of the heat spreader;

FIG. 8A is a cross-section view of a first model of a component assembly including several dies on a common circuit board in which the third embodiment of a heat spreader with cups is used;

FIG. 8B is a cross-section view of a second model of a component assembly including several dies on a common circuit board in which the third embodiment of a heat spreader with cups is used;

FIG. 9 is a top view of the heat spreader with cups;

FIG. 10 is a top view of the heat spreader with cups attached to a substrate with dies;

FIG. 11, consisting of FIGS. 11a-11d, illustrates the manufacturing process for the first model of a package using the third embodiment of the heat spreader; and

FIG. 12, consisting of FIGS. 12a-12d, illustrates the manufacturing process for the second model of a package using the third embodiment of the heat spreader.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

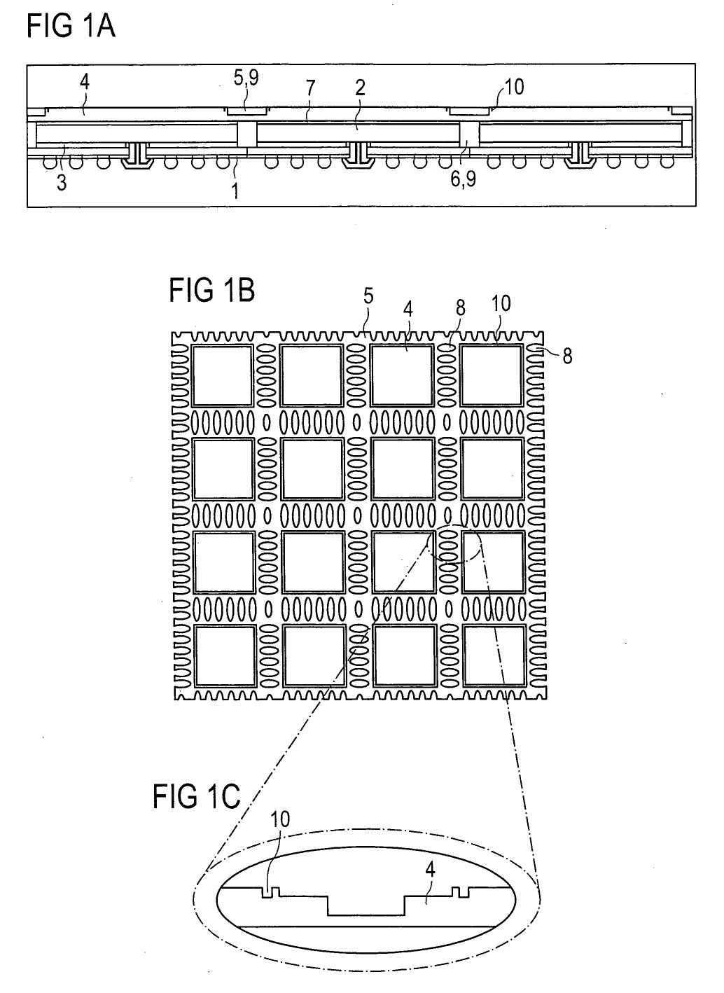

FIGS. 1A, 1B, and 1C are schematic depictions of a first embodiment of the invention in which the heat spreader 4 is made of a substantially flat metal sheet. On the top surface of a circuit board 1 a number of dies 2 are arranged side-by-side and attached to the circuit board 1 by an adhesive epoxy resin 3. On top of the dies 2 a heat spreader 4 is placed. The heat spreader 4 has a number of grooves 5, which are arranged in a grid. The grooves 5 are placed above the clearances 6 by which the dies 2 are separated. The heat spreader 4 is bonded to the dies 2 by an adhesive epoxy resin 7.

In the ground of the grooves 5, a number of openings 8 are arranged that allow a mold compound 9 to freely flow from the top surface of the heat spreader 4 into the clearances 6 between the dies 2 and to fill the grooves 5, thus forming a reinforcing frame. Alongside the grooves 5, furrows 10 are provided to collect excess mold compound 9 so that the top surface of the heat spreader 4 remains free of mold compound 9 for a better heat dissipation.

After the mold compound has cured, solder balls are attached to give electrical connection between chip and board, then the packages can be separated in a cutting or sawing process in which the assembly is cut or sawn apart along the middle of the grooves 5 to obtain semiconductor devices with reinforcing frames.

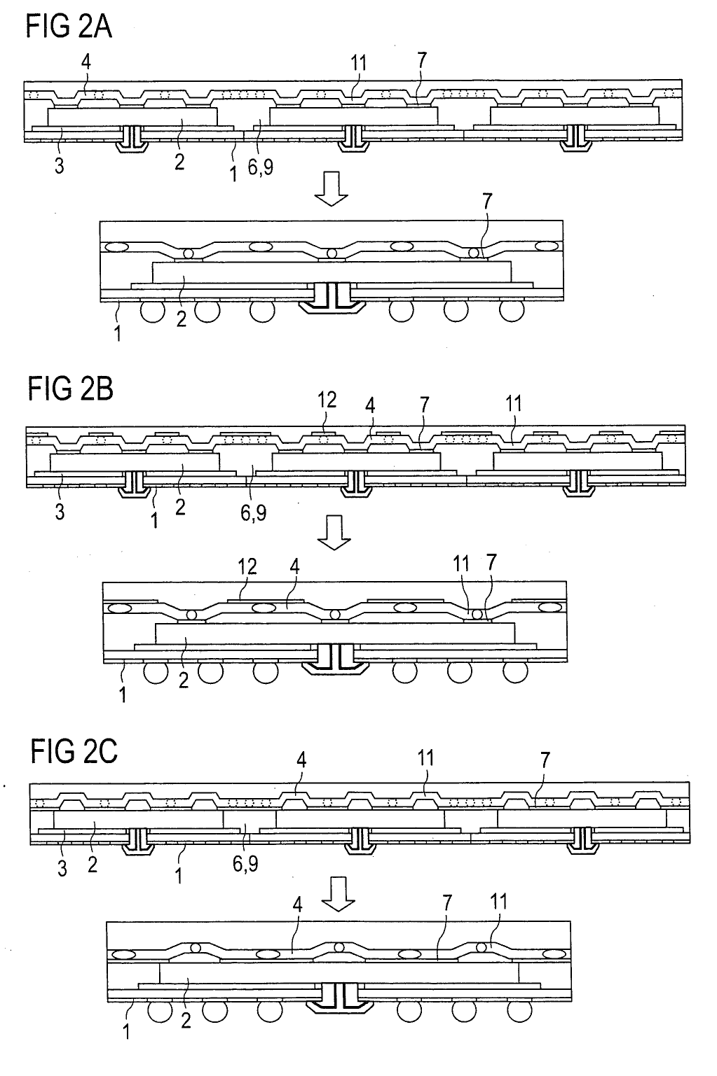

FIGS. 2A, 2B, and 2C are schematic depictions of three variants of a second embodiment of the invention in which the heat spreader 4 is made of a corrugated metal sheet, the stiffening corrugation having the shape of ripples. On the top surface of a circuit board 1 a number of dies 2 are arranged side-by-side and attached to the circuit board 1 by an adhesive epoxy resin 3. On top of the dies 2 a heat spreader 4 is placed. The heat spreader 4 has a stiffening corrugation. The stiffening corrugation is constituted by a number of ripples 11 that run parallel to each other and belong to a primary group of ripples.

The heat spreaders 4 in FIG. 2A and FIG. 2B are attached to the dies 2 in such a manner that the ridges of the ripples 11 of the primary group are bonded to the top surface of the dies 2 by an adhesive epoxy resin 7. The heat spreader 4 in FIG. 2C is attached to the dies 2 in such a manner that the uncorrugated areas of the heat spreader 4 are bonded to the top surface of the dies 2 by an adhesive epoxy resin 7. The heat spreader 4 in FIG. 2B further has a secondary group of ripples 12 that intersect the ripples 11 of the primary group.

The ripples 11 of the primary group project to one side of the metal sheet, namely the bottom side (towards the dies 2) and the ripples 12 of the secondary group project to the other side of the metal sheet, namely the top side (away from the dies 2).

In the ground of the ripples 11 and in the uncorrugated areas of the heat spreader 4, a number of openings 8 are arranged that allow a mold compound 9 to freely flow from the top surface of the heat spreader 4 into the clearances 6 between the dies 2 and between the heat spreader 4 and the dies 2 and to fill the ripples 11 and 12 and to cover the top surface of the heat spreader 4, thus forming a reinforcing frame.

After the mold compound has cured, solder balls are attached to give electrical connection between chip and board. Then the packages can be separated in a cutting or sawing process in which the assembly is cut or sawn apart along the middle of the grooves 5 to obtain semiconductor devices with reinforcing frames.

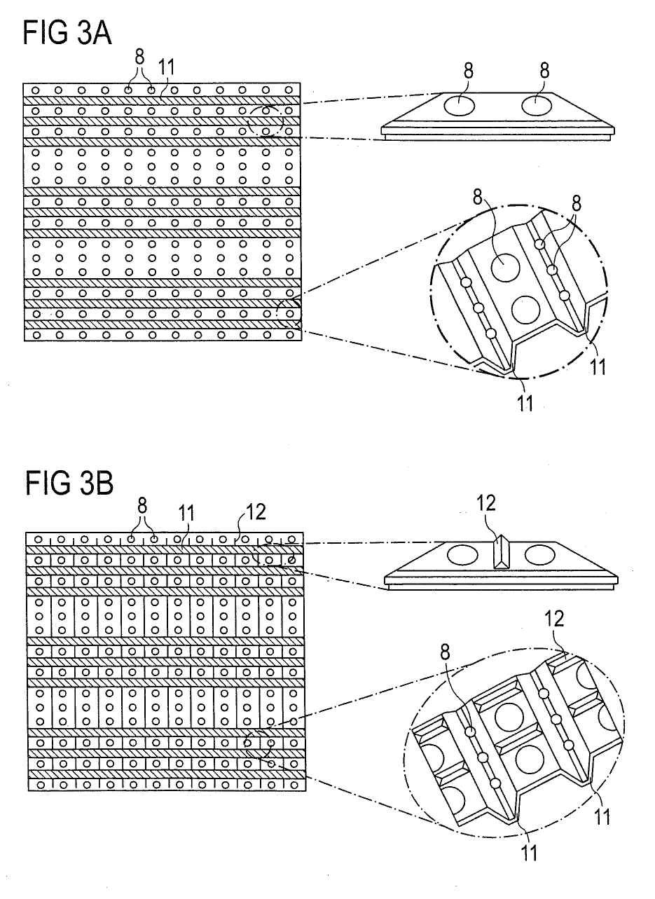

The heat spreader 4 of the second embodiment is again shown in FIGS. 3A and 3B. The surface has been partly magnified in order to explain the structure of the heat spreader 4. The heat spreader 4 has a primary group of ripples 11. In the ground of the grooves formed by the ripples 11, as well as in the areas between the ripples 11, openings 8 are arranged. In FIG. 3B, the heat spreader 4 further has a secondary group of ripples 12 projecting in a direction contrary to that of the first group of ripples 11.

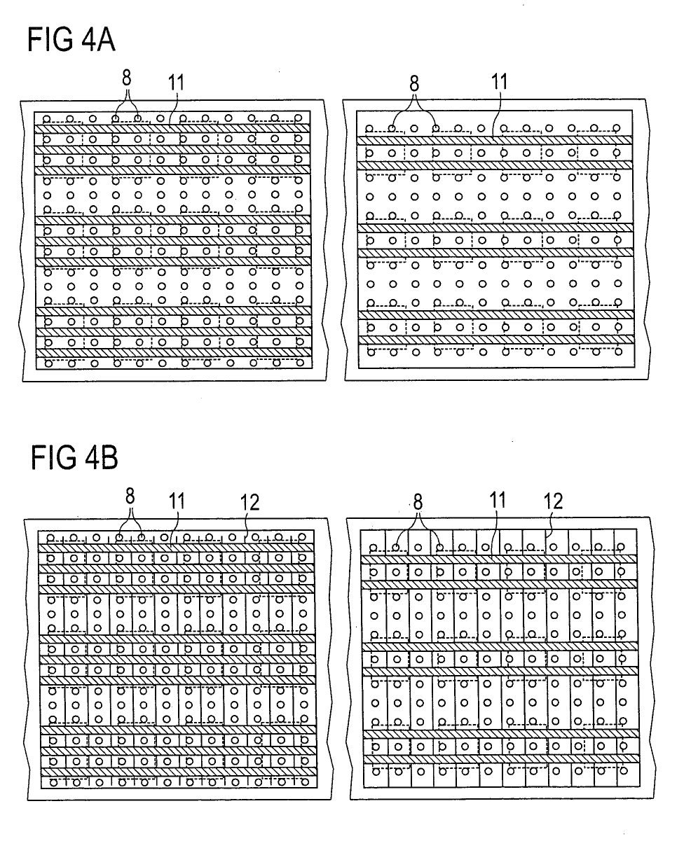

Possible configurations with respect to the assembly of relatively big dies 2 or relatively small dies 2, respectively, are shown in FIGS. 4A and 4B. The ripples 11 of the primary group are arranged so as to be placed above the dies 2 in order to provide for a correct and strong bonding. The positions of the ripples 12 of the secondary group relative to the dies 2, as shown in FIG. 4B, are of minor importance for the effectiveness of the heat spreader 4.

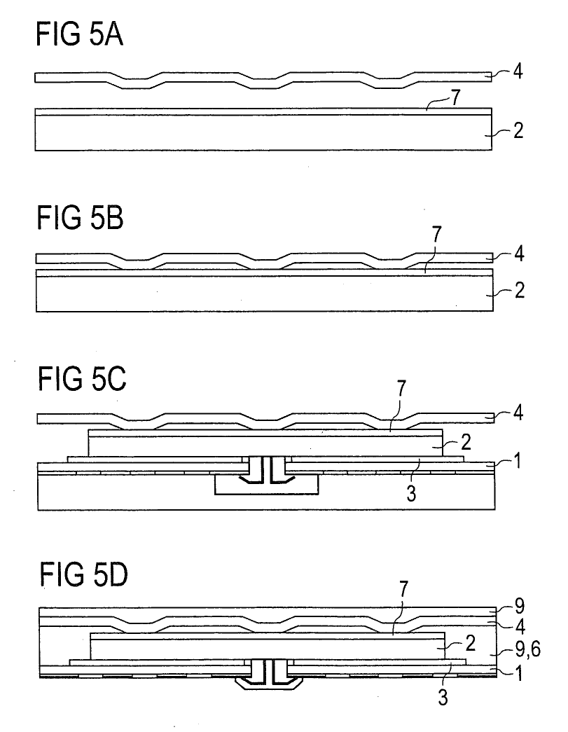

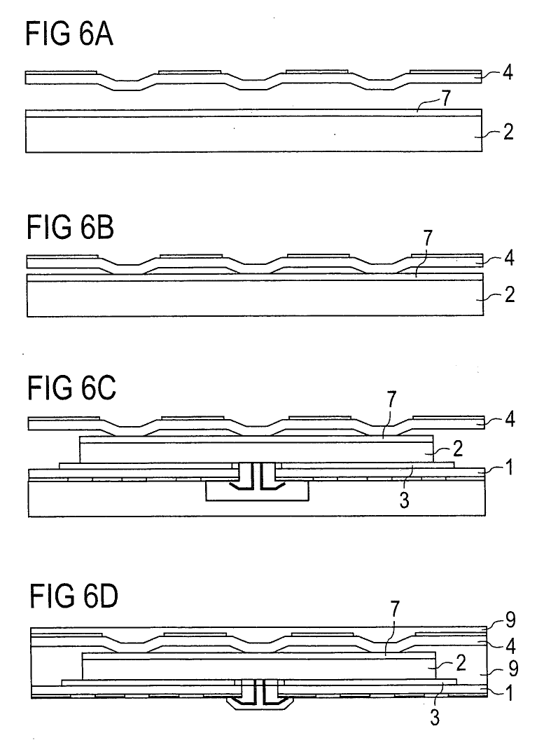

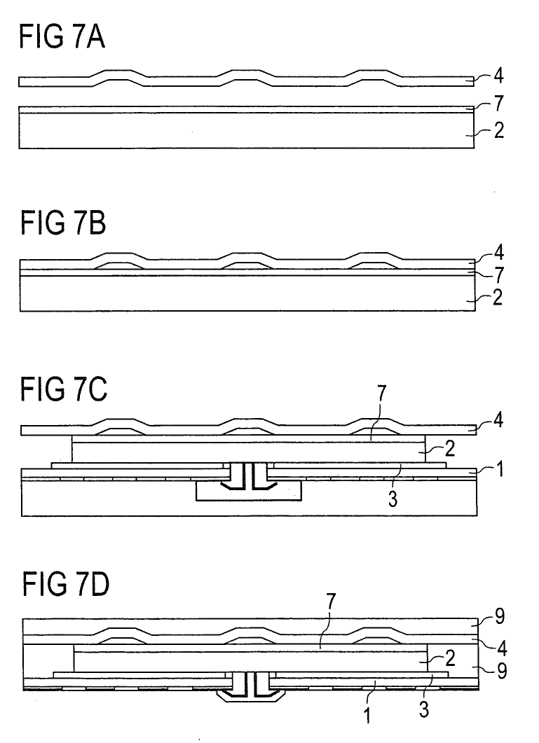

In FIGS. 5, 6, and 7, the manufacturing process of the semiconductor device is illustrated for the three variants of the second embodiment. First, a layer of an adhesive epoxy resin 7 is applied to the top surface of the die 2. Then the heat spreader 4 is bonded to the top surface of the die 2. Finally, the clearances 6 are filled with a mold compound 9 so that the air is driven out of these clearances 6. After the curing of the mold compound 9, solder balls are attached to give electrical connection between chip and board, then the packages are separated in a sawing process.

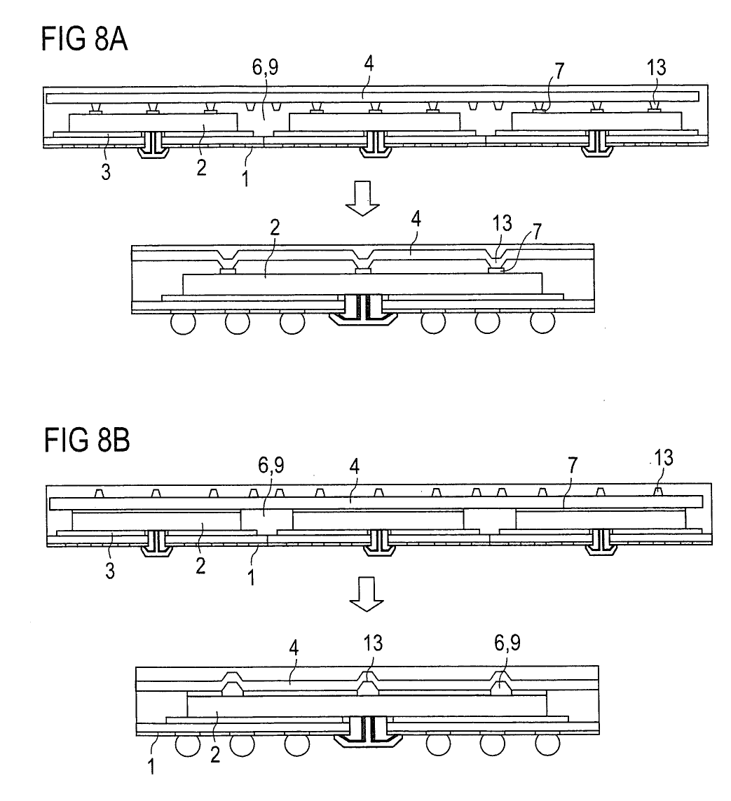

FIGS. 8A and 8B are schematic depictions of two variants of a third embodiment of the invention in which the heat spreader 4 is made of a corrugated metal sheet, the stiffening corrugation having the shape of cups 13. On the top surface of a circuit board 1 a number of dies 2 are arranged side-by-side and attached to the circuit board 1 by an adhesive epoxy resin 3. On top of the dies 2 a heat spreader 4 is placed. The heat spreader 4 has a stiffening corrugation. The stiffening corrugation is constituted by a number of cups 13.

The heat spreader 4 in FIG. 8A is attached to the dies 2 in such a manner that the bottoms of the cups 13 are bonded to the top surface of the dies 2 by an adhesive epoxy resin 7. The heat spreader 4 in FIG. 8B is attached to the dies 2 in such a manner that the uncorrugated areas of the heat spreader 4 are bonded to the top surface of the dies 2 by an adhesive epoxy resin 7 and the cups 13 project upwards.

In the bottom of the cups 13 and in the uncorrugated areas of the heat spreader 4, a number of openings 8 are arranged that allow a mold compound 9 to freely flow from the top surface of the heat spreader 4 into the clearances 6 between the dies 2 and between the heat spreader 4 and the dies 2 and to fill the cups 13 and to cover the top surface of the heat spreader 4, thus forming a reinforcing frame.

After the mold compound has cured, solder balls are attached to give electrical connection between chip and board, then the packages can be separated in a cutting or sawing process in which the assembly is cut or sawn apart along the clearances 6 between the dies 2 to obtain semiconductor devices with reinforcing frames.

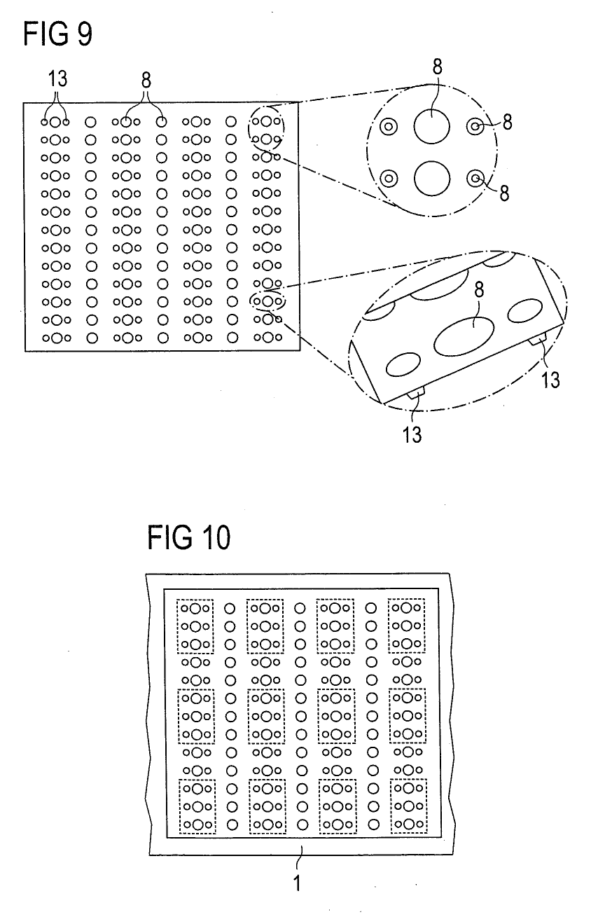

The heat spreader 4 of the third embodiment is again shown in FIG. 9. The surface has been partly magnified in order to explain the structure of the heat spreader 4. The heat spreader 4 has a stiffening corrugation, which is formed by cups 13. In the bottom of the cups 13 as well as in the areas between the cups 13 openings 8 are arranged.

A possible configuration with respect to the assembly of dies 2 is shown in FIG. 10. The cups 13 are arranged so as to be placed above the dies 2 in order to provide for a correct and strong bonding.

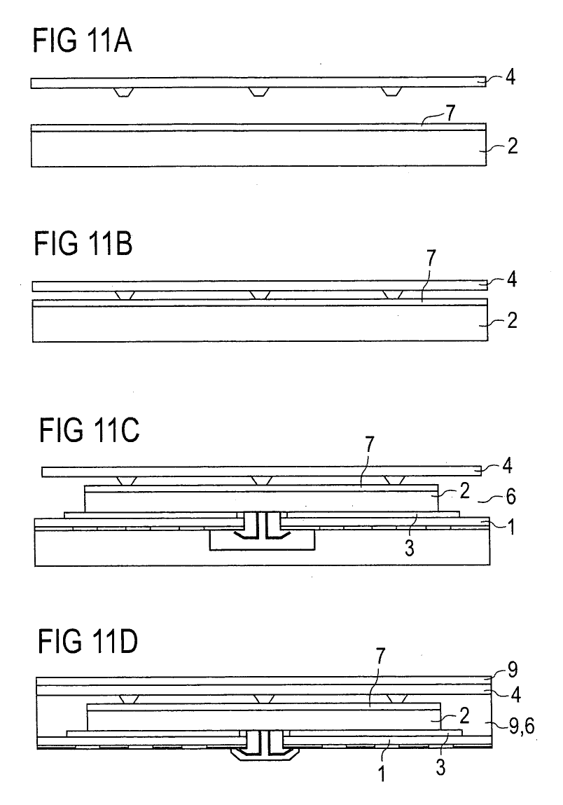

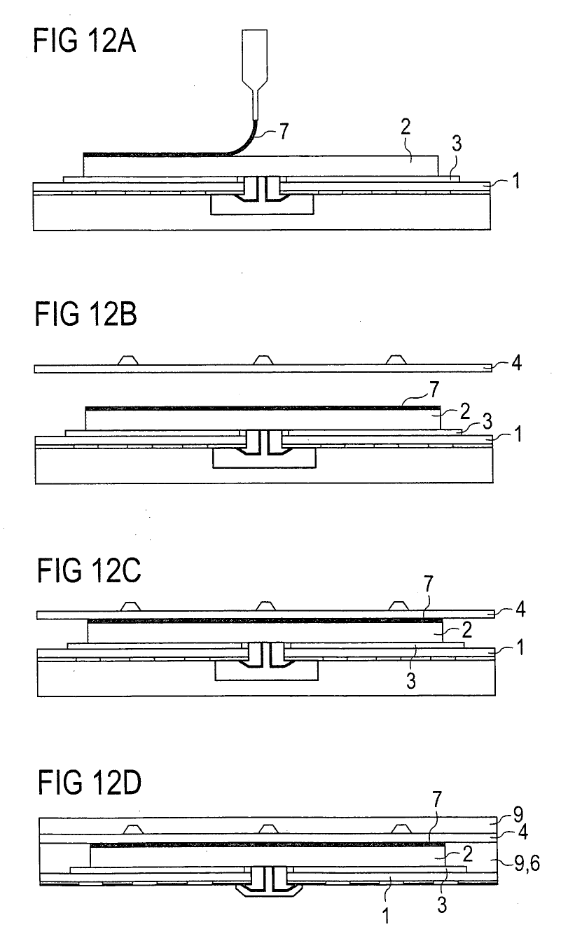

In FIGS. 11 and 12, the manufacturing process of the semiconductor devices is illustrated for the two variants of the third embodiment. First, a layer of an adhesive epoxy resin 7 is applied to the top surface of the die 2. Then the heat spreader 4 is bonded to the top surface of the die 2. Finally, the clearances 6 are filled with a mold compound 9 so that the air is driven out of these clearances 6. After the curing of the mold compound 9 the packages are separated in a sawing process.

What is claimed is:

1. A semiconductor device comprising:
a semiconductor die; and
a heat spreader made of a metal sheet of substantially constant thickness, the metal sheet being perforated by at least one opening to allow for the passage of a mold compound.

2. The semiconductor device according to claim 1, wherein said metal sheet is substantially flat and wherein at least one opening is placed in a groove, which locally reduces the thickness of the metal sheet.

3. The semiconductor device according to claim 2, wherein at least one furrow is provided alongside the groove to collect excess mold compound.

4. The semiconductor device according to claim 2, wherein said metal sheet has a primary group of grooves running parallel to each other and a secondary group of grooves running parallel to each other and intersecting the primary group of grooves.

5. The semiconductor device according to claim 4, wherein a multitude of openings are arranged in columns and rows along the grooves.

6. The semiconductor device according to claim 1, wherein the heat spreader further has a stiffening corrugation.

7. The semiconductor device according to claim 6, wherein the stiffening corrugation has the shape of at least one ripple.

8. The semiconductor device according to claim 7, wherein at least one opening is placed in the groove formed by a ripple.

9. The semiconductor device according to claim 6, wherein the stiffening corrugation has the shape of at least one cup.

10. The semiconductor device according to claim 9, wherein at least one opening is placed in the bottom of a cup.

11. The semiconductor device according to claim 6, wherein the stiffening corrugation is a combination of at least one ripple and at least one cup.

12. The semiconductor device according to claim 11, wherein at least one opening is placed in the bottom of a cup.

13. The semiconductor device according to claim 6, wherein the stiffening corrugation comprises a primary group of ripples running parallel to each other.

14. The semiconductor device according to claim 13, wherein the stiffening corrugation further comprises a secondary group of ripples running parallel to each other and intersecting the primary group of ripples, thereby being disrupted at intersections.

15. The semiconductor device according to claim 14, wherein the primary group of ripples projects to one side of the metal sheet and the secondary group of ripples projects to the other side of the metal sheet.

16. The semiconductor device according to claim 1, further comprising:
a circuit board, the semiconductor die being adhered to the circuit board and electrically coupled to the circuit board; and
molding compound surrounding an upper surface of the semiconductor die and the heat spreader.

17. An anti-warp heat spreader for semiconductor devices, wherein the heat spreader is made of a metal sheet of substantially constant thickness, said metal sheet being perforated by at least one opening to allow for the passage of a mold compound.

18. A method of assembling a semiconductor device, the method comprising:
providing a semiconductor die;
adhering a heat spreader to an upper surface of the semiconductor die, the heat spreader being made of a metal sheet of substantially constant thickness, said metal sheet being perforated by at least one opening; and
applying a molding compound over the upper surface of the semiconductor die, the molding compound passing through the at least one opening in the metal sheet.

19. The method of claim 18, further comprising adhering a lower surface of the semiconductor die to a circuit board prior to applying the molding compound.

20. The method of claim 19, further comprising wire bonding contact pads of the semiconductor die to contact pads of the circuit board such that the components of the semiconductor die are electrically coupled to solder balls of the circuit board.
